(19) United States
(12) Patent Application Publication
(10) Pub. No.: US 2008/0008970 A1
(43) Pub. Date: Jan. 10, 2008

(54) Lithographic Process

(75) Inventors: Roelof WIJNAENDTS, Bad Schoenborn (DE); Christian Buchner, Heidelberg (DE)

Correspondence Address: CROWELL & MORING LLP;INTELLECTUAL PROPERTY GROUP, P.O. BOX 14300, WASHINGTON, DC, 20044-4300, US

(73) Assignee: HEIDELBERG INSTRUMENTS MIKROTECHNIK GmbH

(21) Appl. No.: 11/858,650

(22) Filed: Sep. 20, 2007

Related U.S. Application Data
(63) Continuation of application No. 11/606,336, filed on Nov. 30, 2006, now abandoned.
Application No. 11/606,336 is a continuation of application No. 11/239,381, filed on Sep. 30, 2005, now abandoned.
Application No. 11/239,381 is a continuation of application No. 10/902,817, filed on Aug. 2, 2004, now abandoned.
Application No. 10/902,817 is a continuation of application No. 10/263,768, filed on Oct. 4, 2002, now abandoned.
Application No. 10/263,768 is a continuation of application No. 09/783,531, filed on Feb. 15, 2001, now abandoned.
Application No. 09/783,531 is a continuation of application No. 08/822,032, filed on Mar. 24, 1997, now abandoned.
Application No. 08/822,032 is a continuation of application No. 08/730,440, filed on Oct. 15, 1996, now abandoned.
Application No. 08/730,440 is a continuation of application No. 08/605,803, filed on Feb. 23, 1996, now abandoned.
Application No. 08/605,803 is a continuation of application No. 08/403,448, filed on Mar. 14, 1995, now abandoned.

(30) Foreign Application Priority Data
Mar. 14, 1994 (DE) P4408507.9

(51) Int. Cl. G03F 7/20

(52) U.S. Cl. 430/325

(57) ABSTRACT

In a lithographic process for producing microstructures by means of a direct-write system, predefined areas are exposed by means of a focused beam, particularly a laser beam, in order to produce microstructures. This process is to be further developed such that structures can be produced which are smaller than the optical resolution of the system. For this purpose, the intensity of the focused beam is modulated as a function of the spatial frequency of the structure to be produced, and the structure is produced by removing the photosensitive layer in accordance with a serially scanned grid pattern. The exposure is advantageously carried out in two successive exposure steps.

### CROSS-REFERENCE TO RELATED APPLICATIONS

The present application is a Continuation of application Ser. No. 11/606,336, filed Nov. 30, 2006, which was a Continuation of application Ser. No. 11/239,381, filed Sep. 30, 2005 (now abandoned), which was a Continuation of application Ser. No. 10/902,817, filed Aug. 2, 2004 (now abandoned), which was a Continuation of application Ser. No. 10/263,768, filed Oct. 4, 2002 (now abandoned), which was a Continuation of application Ser. No. 09/783,531, filed Feb. 15, 2001 (now abandoned), which was a Continuation of application Ser. No. 08/822,032, filed Mar. 24, 1997 (now abandoned), which was a Continuation of application Ser. No. 08/730,440, filed Oct. 15, 1996 (now abandoned), which was a Continuation of application Ser. No. 08/605,803, filed Feb. 23, 1996 (now abandoned), which was a Continuation of application Ser. No. 08/403,448, filed Mar. 14, 1995 (now abandoned), which claims priority based on German Patent Application No. P4408507.9 filed Mar. 14, 1994, the entire disclosures of which are hereby incorporated by reference in their entirety herein.

### BACKGROUND OF THE INVENTION

This invention relates to a lithographic process for producing microstructures by means of a direct-write system, in which predetermined areas can be exposed by means of a focused beam in order to produce structures.

A process of this type is known from the journal Solid State Technology, December 1985, pages 81 to 85. According to this process, areas are exposed or not exposed without using masks by direct writing by means of laser beams in order to obtain predetermined structures. By means of the focused laser beam, predeterminable areas, similar to a dot matrix corresponding to the structure which is to be produced, are exposed in order to produce desired structures, particularly microstructures on substrates for microelectronics. The construction of the microstructures will depend to a determinative extent on the light energy of the laser, as well as on the sensitivity of the photosensitive resist which is used. Because of the considerable manufacturing and equipment costs, the process of direct writing, by which structures below 0.25 micrometers can be produced, is currently normally utilized for manufacturing masks for producing microelectronic circuits on semiconductor wafers. A direct-write system has completely incoherent imaging characteristics. In order to obtain transitions or walls of the photosensitive resist which are as steep as possible, the depth of the focus may also be quite large in the case of direct writing.

Published German Patent Application No. 3,118,802 discloses an apparatus for transferring a mask pattern onto a semiconductor wafer, whereby the wafer receives a de-magnified image of the mask pattern. The de-magnification factor is typically 5× or 10×. In this case, several partial exposures are carried out, in which the relative position between the mask pattern and the semiconductor wafer is changed by a very short distance for each partial exposure. Thus, a pattern can be produced on the semiconductor wafer which has smaller line widths than the mask pattern. By means of such lithographic processes using masks for producing microelectronic circuits, microstructures of up to 0.25 micrometers can be produced. This requires optical systems which have a high numerical aperture and a light source with a short wavelength. By means of such systems, which are also called steppers, areas of up to 30×30 mm² may be processed, the complete wafer being exposed in stages with identical images corresponding to the mask. For a coherent system of this type, the maximal frequency to be spatially imaged is only half of that of an incoherent system. This is true although the depth of modulation will continuously decrease in an incoherent system. Therefore, in the currently used stepper systems, the degree of coherence is regularly on the order of 0.5.

Furthermore, published German Patent Application No. 3,401,963 discloses a process for producing photoresist structures with stepped flanks or stepped-back window openings by using masks. Two variants are shown which each start from a glass support metallized on one side. The production of the masks and particularly the precise alignment of these masks with respect to the glass support which is metallized on one side requires fairly high manufacturing expenditures.

Finally, the book Informationstheorie in der Optik (Information Theory in Optics), by Dr. Rainer Roehler, Wissenschaftliche Verlagsgesellschaft mbH Stuttgart, 1967, explains at pages 16 to 21 and 82 to 92, the imaging and interpretation of existing objects. The modulation transfer function (MTF) which determines the imaging characteristics is described in connection with the imaging of incoherently illuminated objects. In coherent imaging, however, adjustment of the modulation transfer function does not result in improvement of the imaging characteristics.

### SUMMARY OF THE INVENTION

In view of the foregoing state of the art, it is an object of the invention to further develop the direct-write process in such a manner that structures can be produced which are smaller than the optical resolution.

This object is achieved by providing a lithographic process for producing a microstructure by means of a direct-write system in which predetermined areas of a photosensitive layer are exposed by means of a focused light beam in order to produce structures, in which the intensity of the light beam is modulated as a function of the spatial frequency of the microstructure to be produced, and the structure is produced by removing the photosensitive layer in accordance with a serially scanned grid pattern.

The process of the invention makes it possible when using a direct-write system to obtain a considerably improved resolution which is increased by the factor 2. A direct-write system is used which has basically incoherent imaging characteristics, as a result of which it has twice the resolution compared to a coherent imaging system, for example, which uses a mask. Although a coherent laser is used as an illumination source, the imaging characteristic of the overall system is incoherent since the system writes only one pixel at a time in a serial manner by scanning across the sample. Consequently, at any given time, one and only one diffraction limited spot is imaged onto the plate, and interference between spatially separate spots on the sample or plate is impossible. Thus, the system behaves completely incoherently. Only within the diffraction limited spot is there any possibility of interference occurring. However, there is only a minor phase change over the spot since the spot size is about the size of the wavelength of the light used, and thus no interference effects are seen here either. Since the imaging characteristic of the overall system is incoherent, the dynamic modification of the modulation transfer function in accordance with the invention leads to improved imaging.

By means of the lithography system, the structure is produced by removing the photosensitive layer in accordance with a serially scanned grid pattern, whereby the intensity of the laser is modulated as a function of the spatial frequency of the structure to be produced. This modulation is carried out electronically by modifying the original image data in the desired manner through data processing and then using the modified image data to write the pattern on the substrate. A direct-writing laser apparatus is used which has a conventional optical imaging system, and microstructures are nevertheless produced which are significantly smaller than the base resolution which can be achieved using this system.

The image is written on the photoresist layer by serially scanning the photoresist layer with the modulated laser light source in the same way a television image is formed by serially scanning the screen pixel by pixel, with the modulation of the laser corresponding to the image which is to be produced. The photoresist layer is thus exposed in a pattern corresponding to the desired image, and the exposed portions can then be removed by known techniques, for example with a chemical developer.

The graphical data is imaged onto the substrate by means of a laser scanning system in combination with an acousto-optical element which turns the laser beam on and off in order to write the image in a manner similar to the operation of a laser printer. In accordance with the invention, the properties of the image, such as its spatial frequency spectrum, can be analyzed before the image is written. The spatial frequency spectrum of an image corresponds to its Fourier transform. For example, a period sinusoidal grid with a definite spacing would yield a single maximum in the spatial frequency spectrum. Any image can be expanded in such frequencies, yielding the spatial frequency spectrum. The modulation transfer function of the laser imaging system including the scanning used in the invention drops off slowly towards higher spatial frequencies, whereby the maximum spatial frequency is at the double frequency as it would be for a coherent imaging system. Using this information, the original image can be modified in such a way that the higher frequencies are boosted in accordance with the modulation transfer function. Doing this yields double the resolution in a manner which is remotely comparable to the Dolby principle used for acoustic systems.

In accordance with the invention, a lithographic process is proposed which enables structures smaller than the theoretical resolution, for example, 0.25 micrometers. This is made possible in accordance with the invention because imaging of the image to be written is carried out in such a manner that the intensity of the spatial frequencies is increased for the higher frequencies. This achieves an almost-flat modulation transfer function (MTF) result in the resolution in the system combined in this manner.

The desired increase of the intensity of the spatial frequencies is carried out in three steps. First, the spatial frequency spectrum of the image to be written is computed electronically. Then, the amplitudes of the various frequencies are modified in accordance with the modulation transfer function of the system. Finally, the modified spatial frequency spectrum is transformed back into a new (modified) image. This new image is then written by the system.

Furthermore, the energy is advantageously adjusted in such a way that the photosensitive resist switches at a level of between 40 to 60%, especially about 50%, so that very steep edges of the resist are also achieved by means of the direct-write system. The term “switching” refers to the characteristic of the photosensitive resist to be exposed only above a predetermined light energy, in which case only after the corresponding exposure are the polymers of the light-sensitive resist modified such that it becomes possible for them to selectively interact with the chemistry of the processes used for further processing.

The percent exposure level of the photoresist is determined in a standard manner as follows. A test exposure is set up whereby a test image is written at a number of different exposure intensities. Since the nominal sizes of the structures of the test images are known, the edge placement of a structure can be plotted against the exposure intensity used. At the 50% exposure level (between 40% and 60%), the edge will be exactly at the nominal position.

The depth of focus is determined in a manner similar to the percent exposure level by making a series of exposures with slightly different focus levels and plotting the resulting structure width (e.g., the width of a thin line) as a function of the focus level. The depth of focus is then determined to be the range in which the focus can be changed without causing a measurable change in the width of the line.

In one particular embodiment of the invention, the technique of multiple development is utilized in order to thus produce a resist structure having a high frequency. In this way, it is possible, in particular, to produce a structure with lines having a width of 0.25 micrometers and intervening spaces of the same size, although the smallest structure to be developed has a size of 0.75 micrometers.

Furthermore, a comparable process can be carried out in two dimensions in order to produce very small positive structures. Finally, any contrast can be produced by means of a negative or positive resist. In one particular alternative embodiment of the invention, very tall structures can be produced by means of the multiple exposure method. In this case, a second layer is exposed directly above a first layer which has already been exposed and developed.

### BRIEF DESCRIPTION OF THE DRAWINGS

The invention will be described in further detail hereinafter with reference to the accompanying drawings in which:

FIG. 1 is a view of the intensity of the light in a layer of a photosensitive resist as a function of the depth of focus of a direct-write system; and

FIG. 2 is a schematic representation of six process steps illustrated one above another.

### DETAILED DESCRIPTION OF PREFERRED EMBODIMENTS

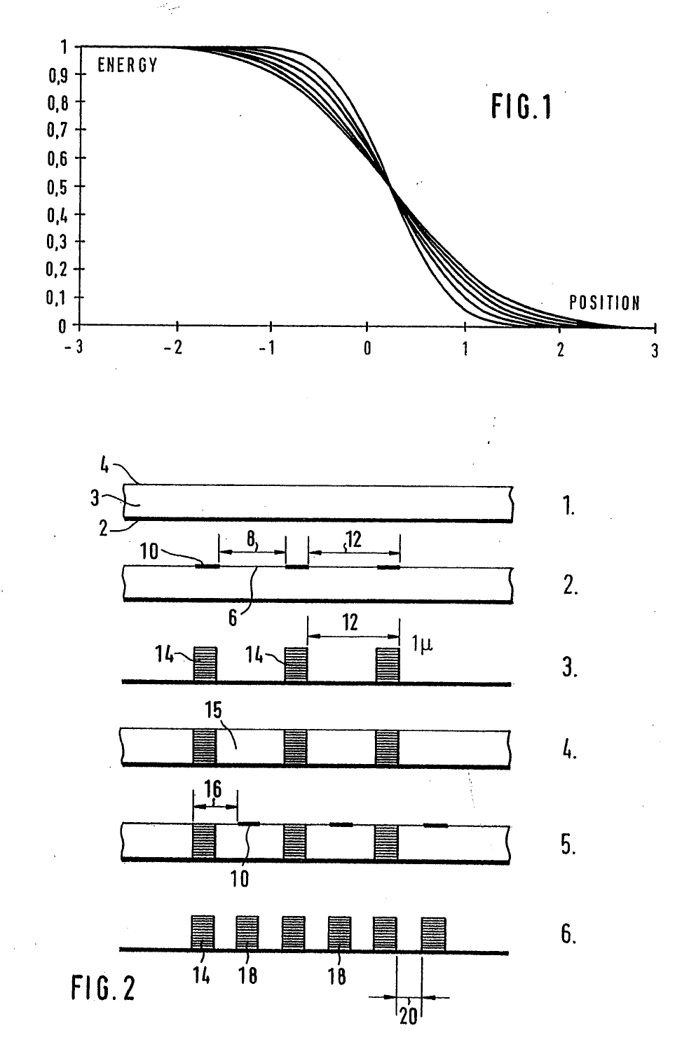

For a direct-write system, FIG. 1 illustrates a standardized representation of the intensity of the light in a layer of the photosensitive resist as a function of the depth of focus, specifically between 0 and 2.5 micrometers relative to a corner or edge. If the photosensitive resist has the characteristic of reacting precisely at an energy or intensity of 0.5, the depth of focus of the direct-write system may be very large. From this it can also be seen that when the exposed image is developed, very steep walls or structure edges are produced.

As noted above, the intensity of the laser is modulated through data processing of the original image data as a function of the spatial frequency of the structure to be produced and then using the modified image data to control the writing operation of the laser to write the image pattern. In this case, a lithographic system is used which produces the object serially by removing the photosensitive layer in accordance with a scanned grid pattern. Although a coherent laser is used as the illumination source, according to the invention, a dynamic modification of the modulation transfer function is carried out so that, on the whole, a true, double resolution is achieved for the overall system.

According to FIG. 2, in a first process step, the substrate 2 is coated with a photosensitive resist 3 whose upper edge is depicted as a continuous line 4.

Subsequently, lines 6 are exposed in the smallest possible width 8, for example, a width of 0.75 micrometers. In accordance with the invention, an optical system is used which has a predetermined optical resolution according to which the smallest structures to be developed have the indicated smallest width 8. For clarity of illustration, the unexposed parts are prominently highlighted. The right edge (as shown in the drawing) of each of the exposed parts 10 has a 1 micrometer spacing 12 with respect to each other. This spacing 12 is referred to as pitch. In the third process step, a first set of structures 14 is developed and produced in accordance with the invention.

According to the invention, a second “exposure step” will now follow. In the fourth process step, photosensitive resist is applied again which now fills the intervening spaces between the previously produced structures 14.

In the important fifth process step according to the invention, an exposure again takes place in a manner similar to process step 2 with the smallest possible writing width 8 of the system, but with a predetermined offset or displacement 16 which in this illustrative embodiment has a size of 0.5 micrometers.

In the sixth process step, the photosensitive resist is developed and a second set of structures 18 is produced in a known manner. Because of the predetermined lateral offset or displacement 16 in accordance with the invention, during the second exposure stage comprising process steps 4 to 6, the structures 18 of the second set are situated between the structures 14 of the first exposure stage. Since the offset or displacement 16 for the second exposure stage amounts to precisely one-half of the pitch 12, the structures 18 of the second set are situated exactly in the middle of the space between the structures 14 of the first set.

Therefore, in accordance with the invention, while using a direct-write system by means of which the narrowest lines in particular have a size of 0.75 micrometers, by means of a predetermined offset in a second exposure stage, structures and/or gaps having widths of 0.25 micrometers can be produced.

As described above, the offset in the second exposure stage occurs in one direction. However, depending on the desired construction of the structures to be produced, in addition to or as an alternative, the displacement may also take place in another direction, for example, perpendicularly with respect to the plane of the drawing, and also produce lines and intervening spaces which have widths of 0.25 micrometers in the other direction.

In accordance with an alternative embodiment of the invention, the second exposure stage is carried out without any offset. The second layer is exposed in accordance with the afore-described steps 4 to 6 directly on top of the exposed layer of the first exposure stage. Thus, a multiple exposure process is disclosed which enables production of very tall structures.

The foregoing description and examples have been set forth merely to illustrate the invention and are not intended to be limiting. Since modifications of the described embodiments incorporating the spirit and substance of the invention may occur to persons skilled in the art, the invention should be construed broadly to include everything within the scope of the appended claims and equivalents thereof.

What is claimed is:

1. A lithographic process for producing a microstructure by means of a direct-write system in which predetermined areas of a photosensitive layer are exposed by means of a focused light beam in order to produce structures, wherein the intensity of the beam is modulated as a function of the spatial frequency of the microstructure to be produced, and the structure is produced serially by removing the photosensitive layer in accordance with a scanned grid pattern.

2. A lithographic process according to claim 1, wherein said focused light beam is a laser beam.

3. A lithographic process according to claim 1, wherein the intensity of the focused beam is increased as the spatial frequency of the microstructure to be produced increases.

4. A lithographic process according to claim 1, wherein a light-sensitive resist is used which switches at an exposure beam energy level of between 40 to 60%.

5. A lithographic process according to claim 4, wherein said light-sensitive resist switches at an exposure beam energy level of about 50%.

6. A lithographic process according to claim 1, wherein, after a first exposure step and subsequent development and formation of a first set of structures, a second exposure step is carried out in which the exposure is carried out with a predetermined displacement, and a second set of structures is produced having a desired offset relative to the first set.

7. A process according to claim 6, wherein the displacement for the second exposure step is chosen such that after final development, the second set of structures are situated in intermediate spaces formed between adjacent structures of the first set during the first exposure step.

8. A process according to claim 1, wherein, after a first exposure step and subsequent development and formation of a first set of structures, a second exposure step is carried out without an offset, and a second set of structures is produced precisely super-imposed on the first set of structures.
